(19) United States
(12) Patent Application Publication
(10) Pub. No.: US 2024/0429016 A1
(43) Pub. Date: Dec. 26, 2024

(54) MAGNETIC VECTOR POTENTIAL-BASED LENS

(71) Applicant: OKINAWA INSTITUTE OF SCIENCE AND TECHNOLOGY SCHOOL CORPORATION, Kunigami Okinawa (JP)

(72) Inventors: Makoto Tokoro SCHREIBER, Okinawa (JP); Matthias WOLF, Okinawa (JP); Cathal CASSIDY, Okinawa (JP)

(73) Assignee: OKINAWA INSTITUTE OF SCIENCE AND TECHNOLOGY SCHOOL CORPORATION, Kunigami Okinawa (JP)

(21) Appl. No.: 18/697,006

(22) PCT Filed: Sep. 27, 2022
(86) PCT No.: PCT/IB2022/059206

§ 371 Date: Mar. 29, 2024

Related U.S. Application Data
(60) Provisional application No. 63/249,777, filed on Sep. 29, 2021.

(51) Int. Cl. H01J 37/141; H01J 37/26

(52) U.S. Cl. CPC H01J 37/141; H01J 37/26; H01J 2237/141

(57) ABSTRACT

Techniques are described for a charged particle optical apparatus that includes a loop of solid material that encloses a bore and a wire winding poloidally wrapped around the loop surrounding the bore. A current is applied to the toroidal winding generating a magnetic field inside the loop along a toroidal direction of the loop and generating magnetic vector potential within the bore. When charged particle(s) pass through the bore of the loop, the magnetic vector potential focuses the charged particles based on the focal point of the charged particle optical apparatus.

### FIELD OF THE TECHNOLOGY

The present invention relates to the field of electromagnetic optics, in particular to magnetic vector potential-based lenses.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Electromagnetic microscopes are used for focusing charged particles onto a sample to be observed. Based on registering the scattering of the charged particles, an enlarged image of the sample may be generated. The focusing ability of such microscopes on a charged particle is usually understood through the Lorentz force, F:

$$F = q ( E + v \times B )$$

in which q is the charge of the charged particle, E is the electric field, v is the velocity of the particle, and B is the magnetic field. Thus, a charged particle may be focused using the electrical field, and an example of this type of lens is an electrostatic “Einzel” lens; or a charged particle may be focused using a magnetic field; an example of this type of lens is a magnetic field-based lens. The magnetic field-based lenses may use an electrical current to generate the necessary magnetic field.

However, both types of these lenses have major shortcomings. Electrostatic lenses do not scale well with particle energy because the electrical field for focusing higher-energy charged particles requires increasingly higher voltages. Unlike the electrostatic lenses, the magnetic field-based lenses scale better with particle energy because the magnetic field may be generated by the current, and the velocity of the particle also aids the focusing ability. However, a magnetic field-based lens can only be convex for negatively charged particles (e.g., electrons), even if the current is reversed. In electron microscopy, the lack of effective concave lenses has been very limiting for the design of optic systems.

Additionally, a magnetic field-based lens introduces significant chromatic as well as spherical aberrations. In particular, with the spherical aberration (the outer rays being differently focused than the inner rays), observations of a sample may require further processing to produce a sharp image.

One way to quantify the focusing effect of a lens and its spherical aberration is to measure the phase shift of the wave of the charged particles as they cross through the magnetic field. To determine the spherical aberration, the calculated phase shift is compared with an ideal lens phase shift.

FIGS. 1A and 1B depict graphs of a phase shift profile of a magnetic field-based lens (110) compared with a phase shift profile of an ideal lens (120) and a phase shift profile for a lens with a third-order spherical aberration (130), in an embodiment. In FIG. 1A, phase shift profile 110 at the edges of the magnetic field-based lens (−1 to −0.4 and 0.4 to 1, r/r) has a dominant spherical aberration, which is much greater than phase profile 130 of a lens with a third degree spherical. Such strong aberrations at the edges of the lens may not allow the full area of the lens to be used, and for a particular size of the specimen, a bulkier lens may be needed.

In order to correct for such aberrations in lenses, several approaches have been introduced:
I. Non-axially symmetric lenses (multi-pole lenses)
II. Space-charges in the beam path
III. Time-varying fields
IV. A lens-mirror combination

One approach for reducing the spherical aberration in a magnetic field-based lens is to use multiple pole electromagnets/magnets. Each portion of such a lens is covered by a different pair of opposing polarity magnets. Accordingly, such an arrangement makes the microscope much bulkier and requires multiple transfer lenses to correct for aberrations.

Additionally, multi-pole lenses are very expensive for microscopes as the lenses add significant length to the column and are generally not straightforward to align. Nevertheless, such lenses add a high degree of tunability to the microscope and have other purposes.

Another approach is to introduce space charges in the beam path using sculpted foils which may produce negative spherical aberrations in scanning transmission electron microscopy. The approach introduces a sample in the path of the charged particle beam. However, this approach reduces the beam intensity as well as introduces other scattering signals into the optics. While the approach may be cost-efficient to correct for spherical aberration, such a lens is not tune-able and must be custom-designed for each microscope. This approach also introduces additionally servicing requirements as the foil may need to be replaced periodically.

The third approach uses time-varying fields and likewise adds complexities to the design of the lens. The final approach, a lens-mirror combination, is mainly used in low-electron energy microscopes. Using such an approach, the electrons must be slowed down before hitting the mirror.

### BRIEF DESCRIPTION OF THE DRAWINGS

In the drawings of certain embodiments in which like reference numerals refer to corresponding parts throughout the figures:

FIGS. 1A/1B are diagrams that depict plots of a phase shift profile of a magnetic field-based lens compared with a phase shift profile of an ideal lens and a phase shift profile for a lens with a second-order spherical aberration, in an embodiment;

FIGS. 2A-2D are diagrams that depict various charged particles entering and exiting a magnetic vector potential lens with different directions of current applied, in one or more embodiments;

FIG. 3 is a schematic diagram of a magnetic field-based lens, in an embodiment;

FIG. 4A is a diagram that depicts a plot of the vector potential field map for an infinite-length solenoid in the azimuthal (z) direction, in an embodiment;

FIG. 4B is a diagram that depicts a plot for the phase shift for an electron passing on the sides of an infinite-length solenoid, in an embodiment;

FIG. 5 is a diagram that depicts a schematic of the geometry of a torus, in an embodiment;

FIG. 6A is a diagram that depicts a schematic of a torus-shaped magnetic vector potential-based concave lens, in an embodiment;

FIG. 6B is a diagram that depicts a schematic of a torus-shaped magnetic vector potential-based convex lens, in an embodiment;

FIG. 7 is a diagram that depicts a plot of magnetic vector potential through an axial cross-section of a toroidal coil, in an embodiment;

FIGS. 8A/8B are diagrams that depict the effect of changing the wavelength of an electron passing through a magnetic vector potential field, in one or more embodiments;

FIGS. 9A/9B are diagrams that depict plots for radial relative electron phase shift profiles for different current directions, in one or more embodiments;

FIG. 10 is a schematic that depicts a magnetic vector potential-based lens correcting the spherical aberration of a focusing charged particle lens, in an embodiment;

FIG. 11 is a schematic that depicts two magnetic vector potential-based lenses of opposing type focal points for condensing the passing charged beam profile into a more intense and more parallel beam profile, in an embodiment;

FIG. 12A is a diagram that depicts a helical winding in the counter-poloidal direction for a magnetic vector potential lens, in an embodiment.

FIG. 12B is a diagram that depicts helical winding(s) in both the poloidal and counter-poloidal direction for a magnetic vector potential lens, in an embodiment.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, structures and devices are shown in block diagram form in order to avoid unnecessarily obscuring the present invention.

### GENERAL OVERVIEW

The approaches herein describe a charged particle focusing apparatus. The apparatus contains a loop of solid material enclosing a bore through which charged particles pass. An example of the loop of solid material is a toroid of ferromagnetic material. In an embodiment, wire(s) are wrapped around the solid material in a poloidal direction to create poloidal wire winding(s), also referred to herein as a “toroidal coil.” The term “poloidal” refers herein to the rotational direction around the cross-section of the solid material, which is orthogonal to the bore of the loop.

In an embodiment, a current is applied to the wire winding, thereby generating a magnetic field within the winding without generating any substantial magnetic field outside of the winding. Accordingly, a magnetic field is created within the solid material, but nearly no magnetic field is generated outside of the solid material, including within the bore of the loop.

While the magnetic field is substantially non-existent outside of the solid material, the techniques described herein generate the magnetic vector potential for the generated magnetic field. The directions of the generated magnetic vector potential are orthogonal to the magnetic field within the loop (e.g., the geometric plane(s) covering the loop and the bore). The magnitude of the magnetic vector potential may be adjusted by adjusting the magnetic flux within a solid substance which may be accomplished by adjusting the current and/or changing the volume of the loop. The generated magnetic potential is greater in the areas closer to the solid material inside the bore and decreases further away from the inner walls of the bore and towards the outside of the loop.

Because the magnetic vector potential changes the phase for a beam of a charged particle(s), the generated magnetic potential generates a lensing effect on the charged particle(s) passing through the bore of the loop of solid material. Changing the direction of the current changes the type of the lensing effect from convex to concave or vice versa, in an embodiment.

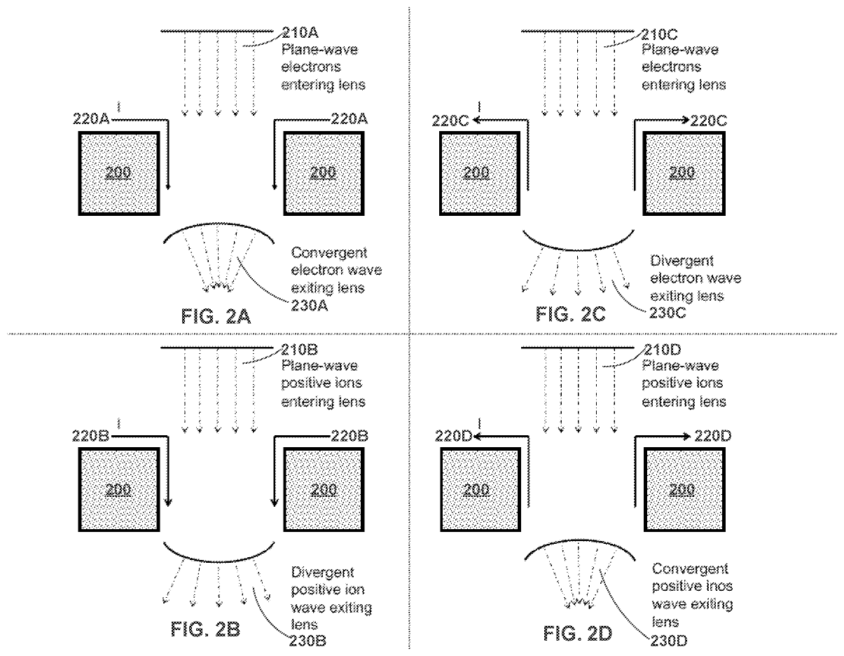

FIGS. 2A-2D are diagrams that depict various charged particles entering and exiting a magnetic potential lens with different directions of current applied, in one or more embodiments. The term “downward poloidal” refers herein to the rotational direction around the cross-section of the loop of solid material from the outside of the loop into the bore in the direction of a beam of charged particles passing through the bore. The term “upward poloidal” refers herein to the rotational direction around the cross-section of the loop of solid material from the outside of the loop towards the bore in the opposite direction of a beam of charged particles passing through the bore.

In an embodiment, the current in the winding is applied in a downward poloidal direction, which generates a convex focusing effect on electron(s) beamed in the same downward direction through the loop. FIG. 2A is a block diagram that depicts the focusing of electrons using a magnetic vector potential-based convex lens, in an embodiment. In FIG. 2A, current 220A is applied in the downward poloidal direction around loop cross-section 200. The magnetic potential within the bore focuses incoming plane wave of electrons 210A into convergent electron wave 230A. In another embodiment, the current in the winding is applied in the upward poloidal direction, which generates a concave focusing effect (diverging effect) on electron(s). FIG. 2C is a block diagram that depicts the focusing of electrons using a magnetic potential concave lens, in an embodiment. In FIG. 2C, current 220C is applied in the upward poloidal direction around loop cross-section 200. The magnetic potential within the bore focuses incoming plane wave of electrons 210C as a concave lens into divergent electron wave 230C.

In an embodiment in which a beam of positive ions is used, the convex and concave focusing effects are generated with the current flowing in the opposite directions as compared to an electron beam. For example, for a downward positron (positive ion) beam, a convex focusing effect is generated when the current is applied in the upward poloidal direction, and a concave focusing effect is generated when the current is applied in the downward poloidal direction.

FIG. 2B is a block diagram that depicts the focusing of positive ions using a magnetic vector potential-based concave lens, in an embodiment. In FIG. 2B, current 220B is applied in the downward poloidal direction around loop cross-section 200. The magnetic potential within the bore focuses incoming plane wave of positive ion(s) 210B as a concave lens into divergent positive ion wave 230B. On the other hand, FIG. 2D is a block diagram that depicts the focusing of positive ions using a magnetic vector potential-based convex lens, in an embodiment. In FIG. 2B, current 220B is applied in the upward poloidal direction around loop cross-section 200. The magnetic potential within the bore focuses on incoming plane wave of positive ion(s) 210D into convergent positive ion wave 230D.

Accordingly, techniques described herein may generate both concave and convex lensing effects for the same type of charged particle beam (electron(s) or positive ion(s)) based on the direction of the current applied through the wire winding of the loop. Thereby, a magnetic vector potential-based lens may be tuned for concave or convex lensing effect through current.

In an embodiment, the strength of the lensing effect, i.e., the focal point of the lens, may be adjusted using the magnitude of the current. The adjustment in the magnitude of the current causes the corresponding adjustment in magnetic potential, the magnitude of which affects the focal point of the lens.

An additional advantage of the magnetic vector potential-based lens is its flexible geometry. The loop of solid material to generate the magnetic potential may be virtually of any shape. In particular, both the cross-section of the loop as well as the shape of the loop can be of any geometry. For example, the loop may be a torus, toroid of a polygon cross-section, or an ellipsoid of any cross-sectional shape, in one or more embodiments. A toroid of rectangular cross-section is particularly convenient for space-constrained environments of electromagnetic microscopes, providing a stackable architecture of multiple toroid magnetic potential lenses, in an embodiment.

Although the techniques herein may refer to the loop of solid substance as a toroid or torus and the wire winding around a poloidal direction of the loop as a toroid coil, the same techniques apply to various embodiments of loop shapes. Such embodiments may include any number of geometries for the loop and its poloidal wire winding. In an embodiment, the solid substance of the loop is a ferromagnetic material to increase the intensity of the magnetic field within the loop and, therefore, the magnetic potential within the bore of the loop.

### Magnetic Field-Based Lens Overview

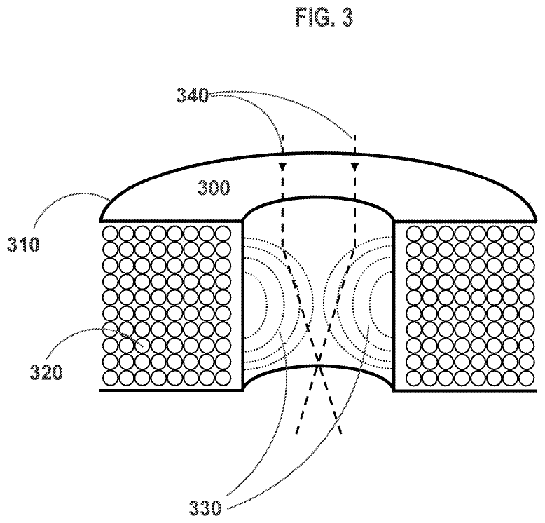

A non-magnetic potential lens, such as a magnetic field-based lens, produces a focusing effect by generating a magnetic field that causes focusing on charged particles passing through its bore of a loop of solid material, in an embodiment. FIG. 3 is a schematic diagram of a magnetic field-based lens, in an embodiment. Lens 300 includes loop of solid material 310, in an embodiment. The material encloses wire coil 320 winded in a latitudinal direction around the bore of the loop.

In FIG. 3, when current is applied to wire coil 320, magnetic field 330 is generated. Magnetic field 330 causes charged particles 340 to focus or diverge depending only on the charge, in such an embodiment. Accordingly, the direction of the current in a magnetic field-based lens has no effect on the type of the lens, making the lens non-tunable. Unlike the magnetic vector potential-based lenses discussed herein, in this embodiment, the magnetic field-based lens is always convex for an electron beam and concave for a positive ion beam. Furthermore, as discussed above, magnetic field-based lenses have a third or higher-order spherical aberration due to the distribution of magnetic fields within the bore.

The focusing effect of the magnetic field-based lens may be represented through a wave perspective based on the relative phase profile, in which the phase of the wavefront is changed based on generated magnetic flux:

$$Δφ = \frac{q}{ℏ} {Φ}_{B} \qquad ( 1 )$$

where q is the electric charge of the particle and h is the reduced Plank's constant. The magnetic flux Φ_{B} is defined as the component of the integrated magnetic field passing through an enclosed surface S, in an embodiment. The magnetic flux depends on the line integral of the vector potential A around the enclosed surface:

$${Φ}_{B} = \int {\int }_{S} B \cdot dS = ∮ A \cdot dl \qquad ( 2 )$$

as B=∇×A. Accordingly, the radial relative phase profile is demonstrated to always be convex for electrons and have a positive spherical aberration coefficient. The relative phase shift profile of a charged particle passing through the magnetic field is independent of the particle velocity, in such an embodiment. It is only through the deflection angle

$${ϵ}_{x} = \frac{{λΔφ}_{x}}{2 πΔ x} \qquad ( 3 )$$

—where x is the direction of the phase shift and Δx is the length over which the phase shift is calculated—that the velocity comes into play through the particle wavelength λ.

In some embodiment, the equation (1) may be equivalently calculated through the magnetic field or the magnetic vector potential due to equation (2). Certain coil geometries may not provide simply connected regions of space, such as an infinity long solenoidal coil or a toroidal coil. In such multi-connected regions, the magnetic field outside the coil is zero and non-zero within the coils. The magnetic vector potential may, however, be generated everywhere but may not be equally distributed at the coil boundary and, therefore, not consistent with equation (1), in such an embodiment.

### Magnetic Potential Overview

In a zero magnetic field region, the non-zero magnetic vector potential may cause a measurable relative phase shift for charged particles. For an electron with charge −qₑ=−1.602×10⁻¹⁹ C, the phase-shift, Δφ_{AB}, may be calculated:

$${Δφ}_{AB} = \frac{- {q}_{e}}{ℏ} ∮ A \cdot dl . \qquad ( 4 )$$

In one or more embodiments, this topological phase-shift effect was produced on the solenoidal coil geometry. However, the electrons traveling on the same side of an infinite-length solenoidal coil may not experience relative phase shifts as described in the equations (4).

In an embodiment, steady-state currents are applied to the coil; the Coulomb gauge ∇·A=0 is the natural gauge. For an example of an infinite-length solenoid with a circular cross-section oriented along the z-axis (azimuthal direction) in cylindrical (r,θ,z) coordinates with a radius of rₛ, winding per unit length NL, and current I₀, the current may be represented as:

$${A}_{is} ( r ) = \{ \begin{matrix}\frac{{μ}_{0} {N}_{L} {I}_{0} {r}_{s}^{2}}{2 r} \hat{θ} , & ( r > {r}_{s} ) \\ \frac{{μ}_{0} {N}_{L} {I}_{0} r}{2} \hat{θ} , & ( r < {r}_{s} )\end{matrix} \qquad ( 5 )$$

Here, μ₀=1.25663706×10⁻⁶ mkg/s²/A² is the permeability of free space. The equation (5) is for an example of an idealized solenoid where the windings have no helicity, and thus no z component to the vector potential exists. The magnetic field may be determined by taking the curl of A, the current. Accordingly, there is a non-zero B inside the solenoid but zero outside of the solenoid.

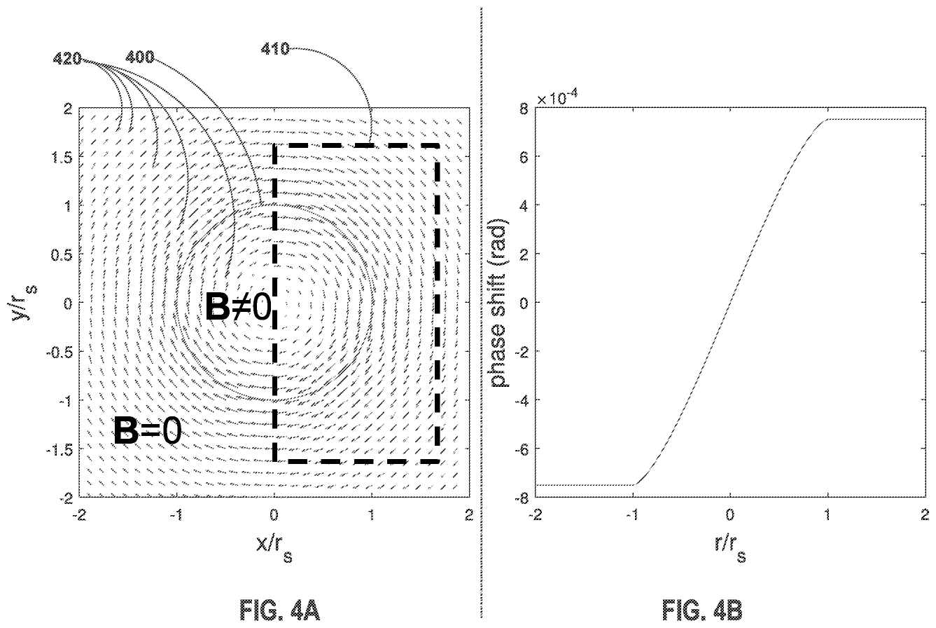

FIG. 4A is a diagram that depicts a plot of the magnetic vector potential field map for an infinite-length solenoid in the azimuthal (z) direction (azimuthal (z) direction is not depicted), in an embodiment. The boundary of the solenoid 400 indicates the border inside of which magnetic field exists (B≠0), while outside of boundary 400, the magnetic field is non-existent (B=0). Dashed rectangle 410 indicates an example loop used to calculate the phase shift relative to an electron passing along the x=0. In such an example, magnetic vector potential field 420 represented by small arrows that lie along the dashed rectangle 410, is used to calculate the phase shift for the electron.

To calculate the relative phase shift profile for electrons passing by the solenoid, a closed-loop may be formed where one path always passes through the solenoid at x=0 parallel to the y-axis. An example loop is represented by dashed-line box 410 in FIG. 4A. For the electron traveling down parallel to the y-direction with the integration performed in the clockwise (CW) direction, the phase shift may be calculated by:

$$- \frac{ℏ}{{q}_{e}} {Δφ}_{x} ( {x}_{1} , {y}_{0} \to {y}_{1} ) = ∮ {A}_{is} \cdot dl \qquad ( 6 )$$

$$= {\int }_{{x}_{0}}^{{x}_{1}} {A}_{i s , x} ( x , y = {y}_{0} ) d x - {\int }_{{x}_{0}}^{{x}_{1}} {A}_{is , x} ( x , y = {y}_{1} ) dx$$

$$+ {\int }_{y 0}^{{y}_{1}} {A}_{i s , y} ( x = {x}_{1} , y ) d y - {\int }_{y 0}^{{y}_{1}} {A}_{i s , y} ( x = {x}_{0} , y ) dy .$$

For an electron traveling +y→−y, the first two integrals will be equal as A_{is,x} is anti-symmetric about y=0. Furthermore, if the electron were traveling from y=∞→y=−0, the first two integrals are zero because Aᵢₛ drops off to zero at infinity in this example.

FIG. 4B is a diagram that depicts a plot for the phase shift for an electron passing on the sides of an infinite-length solenoid, in an embodiment. For this example, such an electron passes outside of boundary 400, where the magnetic field is non-existent, but the magnetic potential does exist. The current used in this example is I₀=1A, and the radius of the solenoid (boundary 400) is rₛ=500 nm.

As depicted in FIG. 4B, the relative phase shift is flat outside the solenoid but of opposite polarities on either side of the solenoid. Thus, if electrons passing on either side of the solenoid are interfered with, a shift in the interference pattern is observed as in this example. A shift in the diffraction pattern is also observed. Analysis of single-slit diffraction with a solenoid to the side of the slit may conclude that the solenoid has no effect on the diffraction pattern. This is apparent from the phase shift profile in FIG. 4B as electrons passing on the same side of the solenoid experience no relative phase shift. No relative phase shift is a consequence of the 1/r drop-off of the vector potential magnitude outside the solenoid which is a further consequence of the topology of the system. A common misconception about the phase shift effect is that it only applies to closed loops enclosing the non-zero magnetic field. While this is true for an infinite-length solenoidal coil, techniques discussed herein also apply to the case of a toroidal coil due to a difference in the system topology.

### Magnetic Vector Potential-Based Lens

To achieve a relative phase-shift of a beam of charged particles, and thus, a lensing effect, techniques described herein use the magnetic vector potential generated by applying current to the poloidal wire winding around a loop. Examples of such wiring, a toroidal coil, may be thought of as a solenoid in which the ends are connected or as wires wound about a donut-shaped solid material. The donut-shaped solid material is referred to herein as a torus. While many examples herein are in the context of a torus with circular axial and planar cross-sections, embodiments are not so limited. For example, instead of a torus, any toroid or a loop of any geometry having a differently shaped cross-section is readily replaceable, and the same techniques are applicable to such shaped loop geometry having a poloidal wire winding. Non-limiting examples of such geometries include a rectangular toroid or a square-shaped loop of a rectangular cross-section.

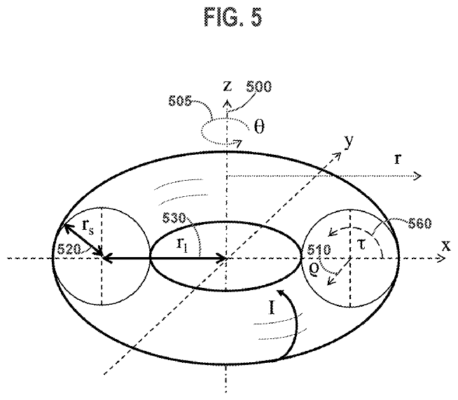

FIG. 5 is a diagram depicting a schematic of the geometry of a torus, in an embodiment. The parameters of cylindrical (r,θ,z) and simple toroidal (ρ,θ,τ) coordinates are shown in relation to Cartesian (x,y,z) coordinates. Both coordinate systems may describe the torus, cylindrical and simple toroidal (ρ,θ,τ). The θ (505), which is common to cylindrical and simple toroidal coordinates, is known as the toroidal (also referred to above as latitudinal) direction, and r (560) is the poloidal direction.

FIG. 5 further depicts the relation between the coordinates, and the major and minor radii are depicted. The major radius rₗ (530) is the length from the azimuthal axes at z (500)=0 to ρ (510)=0. The minor radius rₛ(520) is the maximum value for p (510) before leaving the torus volume. In this case, two radii are used to describe the geometry of the torus; the major radius rₗ(530) and minor radius rₛ (520). This ratio of these radii is the inverse torus aspect ratio

$$ζ = {r}_{s} / {r}_{1} \qquad ( 7 )$$

and can be used to define a shape factor for a torus with a circular axial cross-section of

$$g = 2 \frac{1 - {( 1 - {ζ}^{2} )}^{1 / 2}}{{ζ}^{2}} . \qquad ( 8 )$$

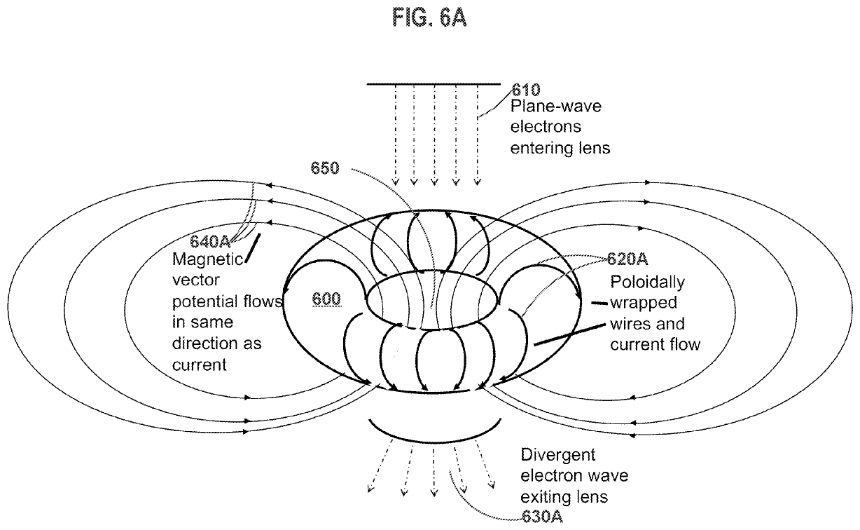

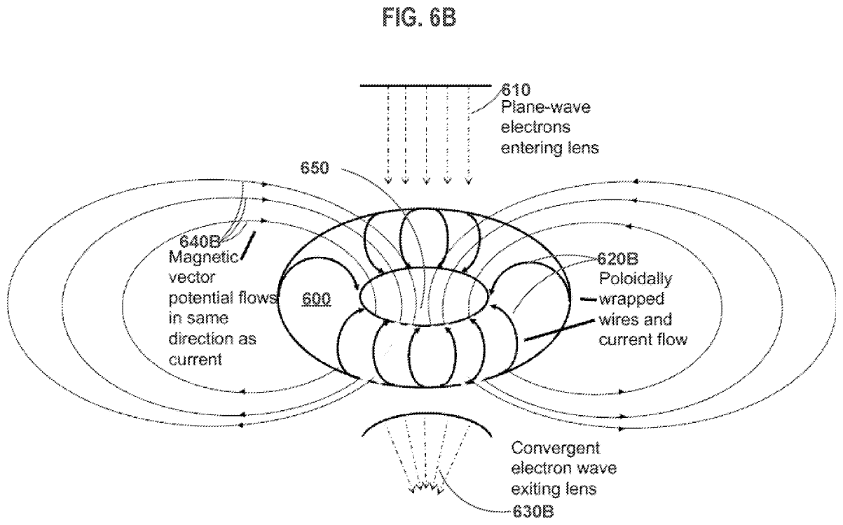

FIG. 6A is a diagram that depicts a schematic of a torus-shaped magnetic vector potential-based concave lens, in an embodiment. Electron beam 610, one or more electrons at a time, enters lens 600. In an idealized example, current 620A flows only in the poloidal direction (having no components in other directions) within the toroidal coil of lens 600. To generate a divergent electron wave, current 620A is applied in the upward poloidal direction within the toroidal coil of lens 600, in this embodiment. Applying current 620A in the upward poloidal direction generates a magnetic field within the solid material of torus 600 in the counterclockwise toroidal direction. By generating the magnetic field, current 620A also generates magnetic potential 640A outside of torus 600 in the same direction as current 620A, in the upward poloidal direction through bore 650 orthogonal to the magnetic field and thus, orthogonal to toroidal plane(s) covering bore 650 of torus 600.

Plane-wave of charged particles 610, which are electrons in this embodiment, pass through magnetic potential 640A within bore 650 of lens 600. Magnetic potential 640A within bore 650 causes the plane wave of electrons 610 to diverge. The electrons that exit bore 650 have divergent wave 630A corresponding to the concave focal point of lens 600.

Similarly, FIG. 6B is a diagram that depicts a schematic of a torus-shaped magnetic vector potential-based convex lens, in an embodiment. To generate a convergent electron wave, current 620B is applied in the downward poloidal direction within the toroidal coil of lens 600. Applying current 620B in the downward poloidal direction generates a magnetic field within the solid material of torus 600 in a clockwise toroidal direction. By generating the magnetic field, current 620B also generates magnetic potential 640B outside of torus 600 in the same direction as current 620B, in the downward poloidal direction through bore 650.

Plane-wave of charged particles 610, which are electrons in this embodiment, pass through magnetic potential 640B within bore 650 of lens 600. Magnetic potential 640B within bore 650 causes the plane wave of electrons 610 to converge. The electrons that exit bore 650 have convergent electron wave 630B corresponding to the convex focal point of lens 600.

For such embodiments, in the Coulomb gauge, the vector potential outside of the toroidal coil with a circular cross-section is closely related to the magnetic field from circular current loop 620 A/B of radius rₗ.

$${A}_{t , outside torus volume} ( r , θ , z ) = {r}_{S} {B}_{l} ( r , θ , z ) \qquad ( 9 )$$

where current loop 620 A/B has a total current

$${I}_{l} = ( \frac{ζ}{2} ) N {I}_{t} g \qquad ( 10 )$$

running through the coil (although the current density inside the wire may not be uniform). Here, N is the total number of loops around torus 600, and Itis the current flowing through the wire around the torus. For a simple current loop, the magnetic field Bₗ=B_{l,r}+B_{l,z}z

$${B}_{l , r} ( r , θ , z ) = \frac{{μ}_{0} {I}_{0}}{2 π} \frac{z}{\sqrt{{( r + {r}_{l} )}^{2} + {z}^{2}}} [ - K ( {k}_{c} ) + \frac{{r}^{2} + {r}_{l}^{2} + {z}^{2}}{{( r - {r}_{l} )}^{2} + {z}^{2}} E ( {k}_{c} ) ] \qquad ( 11 )$$

$${B}_{l , z} ( r , θ , z ) = \frac{{μ}_{0} {I}_{0}}{2 π \sqrt{{( r + {r}_{l} )}^{2} + {z}^{2}}} [ K ( {k}_{c} ) - \frac{{r}^{2} - {r}_{l}^{2} + {z}^{2}}{{( r - {r}_{l} )}^{2} + {z}^{2}} E ( {k}_{c} ) ] \qquad ( 12 )$$

where

$${k}_{c}^{2} = \frac{4 {r}_{l} r}{{( r + {r}_{l} )}^{2} + {( z - {z}_{0} )}^{2} ,} \qquad ( 13 )$$

and K(k) and E(k) are the complete elliptic integral functions of the first and second kind

$$K ( k ) = {\int }_{0}^{π / 2} \frac{d {θ}^{′}}{{( 1 - {k}^{2} sin {θ}^{′} )}^{1 / 2}} \qquad ( 14 )$$

$$E ( k ) = {\int }_{0}^{π / 2} {( 1 - {k}^{2} sin {θ}^{′} )}^{1 / 2} d {θ}^{′} . \qquad ( 15 )$$

The magnetic field outside the torus is zero, in such embodiments. Note that the drop-off of the vector potential away from the torus is not 1/r as with the infinite circular solenoid.

The vector potential inside the torus volume may not have a compact expression, but the magnetic field inside the torus may be compactly expressed by

$${B}_{t , i nside torus volume} ( r , θ , z ) = \frac{{μ}_{0} N {I}_{t}}{2 π r} \hat{θ} . \qquad ( 16 )$$

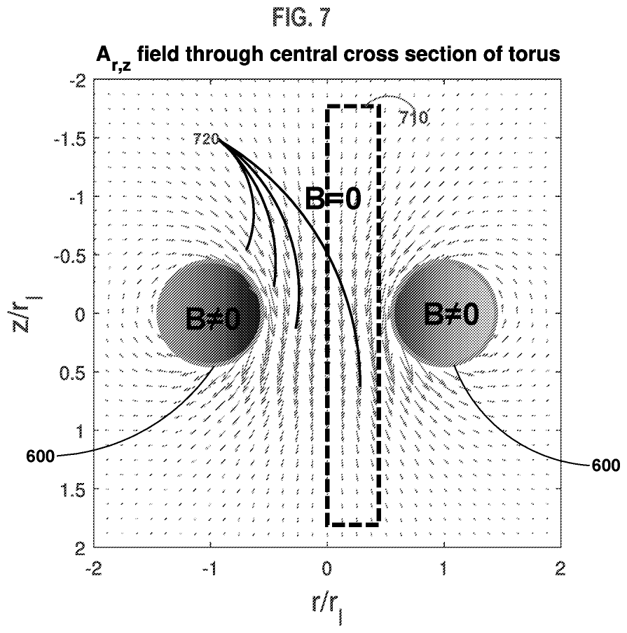

FIG. 7 is a diagram that depicts a plot of magnetic vector potential through an axial cross-section of a toroidal coil, in an embodiment. The arrows represent vector potential 720 outside torus 600. The magnetic field inside the torus (B≠0) is the strongest closest to torus 600 edge neighboring the bore (r/rₗ=0) but is non-existent (B=0) outside of torus 600. Dashed rectangle 710 indicates an example loop used to calculate the relative phase shift.

Near the z-axis of torus 600, the potential is nearly vertical, orthogonal to the toroidal plane of torus 600. The magnitude of the potential is strongest near the walls of torus 600, as depicted with a greater density of magnetic potential vectors in FIG. 7. Unlike the symmetry of the magnetic potential field for a solenoid depicted in FIG. 4A, the magnitude of the potential on the inner and outer walls of the torus is asymmetric, as depicted in FIG. 7. The magnetic potential is weaker on the outside of the torus than the inside of the bore, especially closer to the inside walls of the torus. In an embodiment, when the current direction is reversed, the direction of the vector potential also switches (as the direction of the magnetic field within the torus 600, not depicted in FIG. 7).

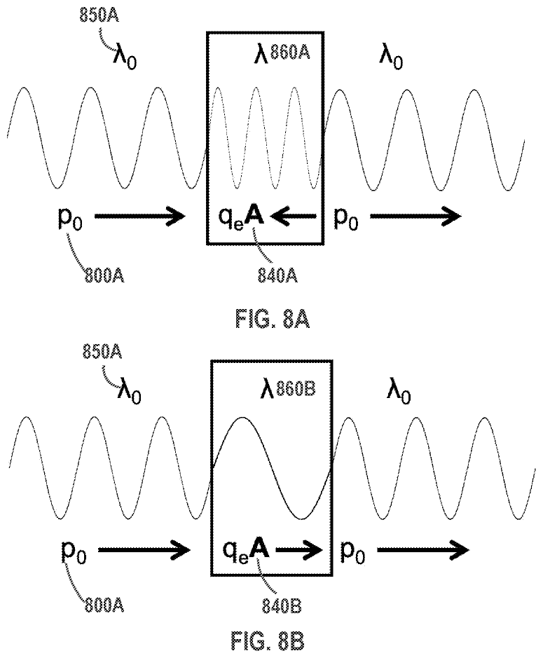

Based on the topological phase effect, the magnetic potential causes the beam of charged particles entering the bore to experience a phase shift, in an embodiment. FIGS. 8A/8B are diagrams that depict the topological effect of changing the wavelength of an electron passing through a magnetic potential field, in one or more embodiments. In FIG. 8A, an electron having momentum 800A opposing magnetic potential 840A changes its wave property from having wavelength 850A to new wavelength 860A in this example. Because potential 840A and electron 800A are in the opposite direction, original wavelength 850A is reduced (“squeezed”) into lower wavelength 860A. This change in the wavelength of each electron passing through the bore of the lens causes the relative phase shift.

Unlike FIG. 8A, in FIG. 8B example, magnetic potential 840B is in the same direction as the momentum of electron 800A. Accordingly, using the wave property of the electron, initial wavelength 850A of an electron is changed with magnetic potential 840B into new wavelength 860B. Because potential 840B and electron 800A's momentum are in the same direction, original wavelength 850A is increased (“expanded”) into greater wavelength 860B.

The phase shifts depicted are the phase shifts relative to the phase shift experienced by the wave property of a charged particle crossing through the optical axis, z-axis (the central point of the bore). In such embodiments, the relative phase shift for electrons traveling parallel to the azimuthal axis of torus 600 is calculated using the z-axis as the reference path,

$$- \frac{ℏ}{{q}_{e}} {Δφ}_{r} ( {r}_{1} , θ , {z}_{0} \to {z}_{1} ) = ∮ {A}_{t} \cdot dl \qquad ( 17 )$$

$$= {\int }_{{r}_{0}}^{{r}_{1}} {A}_{t , r} ( r , θ , z = {z}_{0} ) d r - {\int }_{{r}_{0}}^{{r}_{1}} {A}_{t , r} ( r , θ , z = {z}_{1} ) dr$$

$$+ {\int }_{{z}_{0}}^{{z}_{1}} {A}_{t , z} ( r = {r}_{1} , θ , z ) d z - {\int }_{{z}_{0}}^{{z}_{1}} {A}_{t , z} ( r = {r}_{2} , θ , z ) dz .$$

In this example, because A_{t,r} is anti-symmetric about z=0, the first two integrals are equal for an electron traveling +z→−z. If the electron were traveling from z=∞→z=−∞, the first two integrals would be zero as |Aₜ| drops off to zero at infinity.

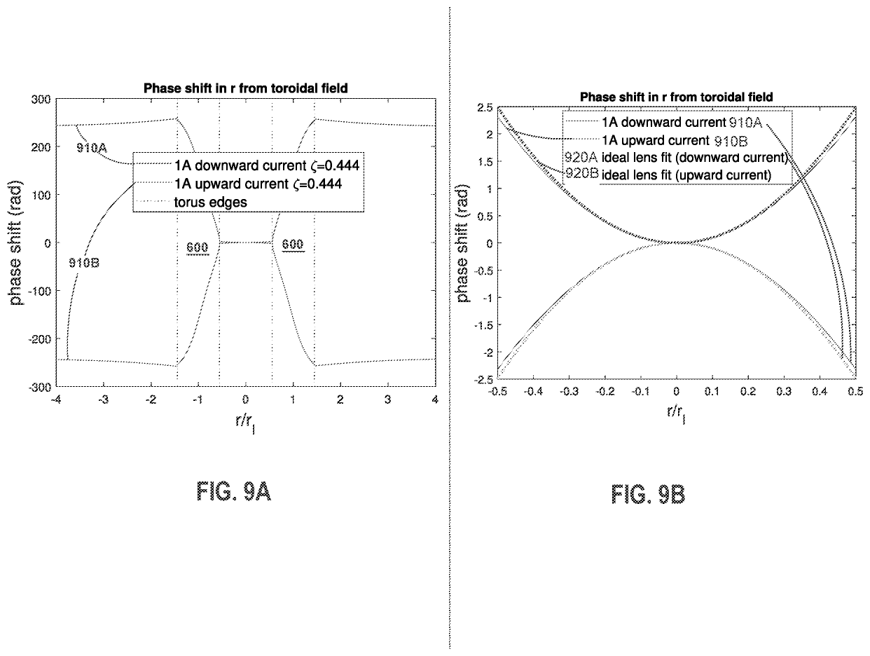

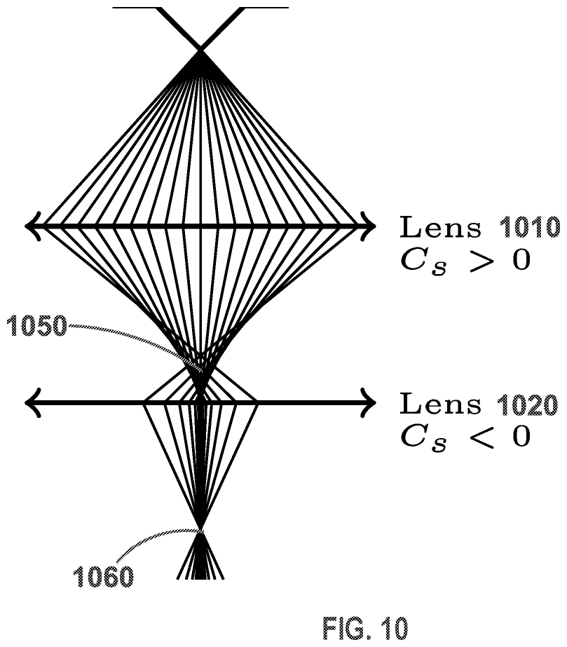

FIGS. 9A and 9B are diagrams that depict plots for radial relative electron phase shift profiles for different current directions, in one or more embodiments. The current directions are given with respect to the inner wall of the torus (downward poloidally and upward poloidally). In FIG. 9A, the dotted vertical lines represent the boundaries of torus 600. Parameters used in this embodiment are rₛ=400 nm, and rₗ900 nm (ζ=0.444), and NIₜ=1A to measure the depicted phase shifts in FIGS. 9A and 9B.

In such an embodiment, phase shift profiles (910A/B) reverse with the current direction, unlike the case for a solenoidal magnetic field-based lens. Phase shift profile 910A corresponds to a downward poloidal current being applied to the toroidal coil wiring. When the upward poloidal current is applied, the phase shift profile 910B is generated for electrons passing through the bore.

As depicted in FIG. 9A, for both applications of currents 910A/910B, there is a large phase shift between the regions of r<rₗ−rₛ (axial region) and r>rₗ+rₛ (outer region). Unlike in the case of the infinite-length solenoid, in these embodiments, the relative phase shifts outside of the torus volume are not completely flat. Far from the torus, the phase profile flattens out as the vector potential decays.

FIG. 9B is a diagram that depicts plots of zoomed-in portions of FIG. 9A for the bore area of the torus, in an embodiment. In FIG. 9B, near the torus edges at the bore, the phase shift profile is curved. This phase shift profile gives the torus with generated magnetic potential lensing effect on entering charged particles.

In an embodiment, the focusing power of a magnetic potential lens is proportional to the magnitude of the vector potential in the axial region of the loop (center of the bore). To increase (or decrease) the vector potential within the bore, the magnetic flux inside the loop JA: | is increased (or, respectively, decreased). The flux may be increased by increasing the volume of the bore as well as by the selection of the solid material for the loop. Similarly, the smaller volume of the bore would yield less flux, thus lesser magnetic flux and potential and thus, lesser focusing power.

In an embodiment, to achieve greater volume, especially for an electron microscope application, rather than using a circular cross-sections loop, a rectangular cross-section loop is used. While the inner and outer radii of the loop (such as torus) will be limited by the existing dimensions of the microscope column, the loop (torus) is elongated along the z-axis, in an embodiment. This is analogous to forming a solenoid from simple current loops.

Alternatively or additionally, the focusing power is adjusted by having a higher permeability substance for the solid substance of the loop. If the core of the loop is not vacuum but the toroidal wiring were wrapped around some core material, then μ₀ in equations (9), (11), (12), and (16) would be replaced by the magnetic permeability μ. For example, iron has a high magnetic permeability, although the value may vary drastically with the purity and hysteresis. High purity (99.95%) iron may exhibit a maximum relative permeability of μ=200,000μ₀ but an initial permeability of μ=10,000μ₀. In such an embodiment, the selection for the solid substance for the loop may increase the focusing power of the lens by several hundred times, just as the pole-pieces around the solenoidal coils in magnetic field-based lenses act to concentrate the magnetic field. The focal length may vary linearly with μlₜN (the current, the permeability of the substance, and the number of windings). In an embodiment in which greater or lesser current is applied, the focal length is shortened or lengthened, respectively. Additionally or alternatively, the focal length non-linearly depends on the shape factor up to the magnetic saturation of the core.

### Aberrations of Magnetic Vector Potential-Based Lens

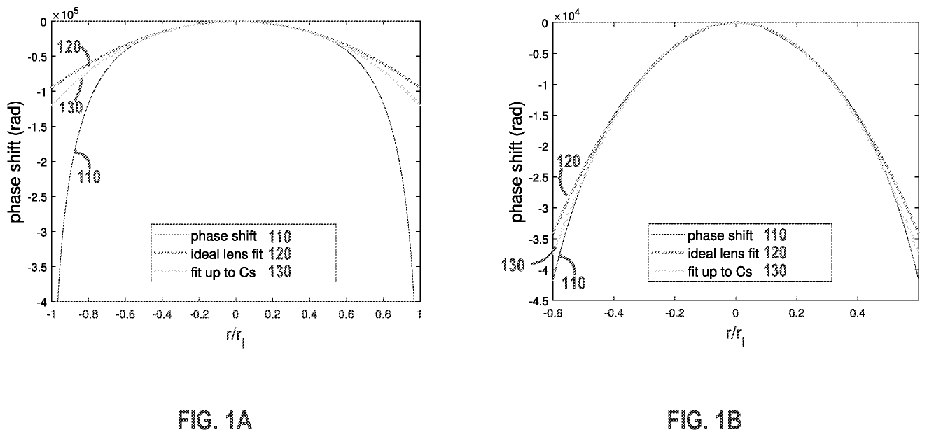

Inside the loop (e.g., torus) and especially within the bore of the loop, a nearly linear phase ramp may be generated. The deviations from linearity may be due to the circular axial cross-section of the torus. In FIG. 9B, the deviation from the linearity of the phase shift profile closely matches the parabolic phase shift profile of an ideal lens, in an embodiment. An example of an ideal lens phase shift for 300 keV electrons is depicted in FIG. 9B, and is represented by:

$${Δφ}_{ideal} = - \frac{π {r}^{2}}{λ f} \qquad ( 18 )$$

where f is the focal length (positive=convex, negative=concave). The fit to the ideal lens 920A/920B by 910A/910B is much closer than for a magnetic field-based lens as described in FIGS. 1A/1B.

Based on FIGS. 9A/9B plots, the focusing effect is weaker far from the z-(optic) axis, in such embodiments. Accordingly, the example lens with a convex profile has a negative spherical aberration coefficient, and for the concave lens, the spherical aberration coefficient is positive. The addition of a small negative third-order spherical aberration term (C₃) fits the toroidal phase profile for both concave and convex lenses almost perfectly. This is an improvement over a magnetic field-based lens (e.g., solenoidal coil lens) with the same inner radius as the example torus. The solenoidal coil lens has a positive and much larger than C₃ (third-order) spherical aberration. For the solenoidal coil, progressively smaller higher-order spherical aberrations terms up to C₉ (ninth order spherical aberrations) are required to well fit the phase profile of an ideal lens. These higher-order aberrations are very dominant, especially near the edges of the solenoidal lens, as depicted in FIGS. 1A/1B.

Therefore, a toroidal coil lens may focus charged particles passing through its bore with the magnetic vector potential and act as a magnetic field-based lens with a small spherical aberration coefficient in the opposing direction to the focus, in an embodiment. The lens has inherently much lower-order spherical aberrations than solenoidal magnetic field-based lenses; thereby, the whole bore may be used for lensing. Furthermore, such a lens may be tuned to be concave or convex based on the current direction. As the wavelength dependence for magnetic field-based lenses is represented by eq. (3), a toroidal coil lens in the focusing configuration may have a positive chromatic aberration coefficient just as the solenoidal magnetic field-based lenses but a negative chromatic aberration in the divergent configuration of a magnetic-potential-based lens. Accordingly, a magnetic vector potential-based lens with a negative spherical aberration may be used to reduce positive spherical aberration of another lens (e.g., solenoidal lens as described in the section below) while maintaining the round lens symmetry without any introduction of the specimen into a microscope.

Due to the lack of vector potential in the toroidal direction, a magnetic vector potential-based lens produces upright magnified image, in one or more embodiments. The absence of any image rotation is an improvement over other types of lenses that cause a rotation of the magnified image.

When the rotational symmetry of the toroidal lens is deformed into a polygonal donut, such a multipole-type lens continues to generate the topological phase-shift effect when a magnetic potential is generated by the current using techniques described herein. The magnitude of the spherical aberrations for such a lens may change based on the geometrical shape of the magnetic-potential lens. Cross-section of the loop and/or the shape of the loop may change the spherical and/or chromatic aberrations.

### Improving Lens Effectiveness

In an embodiment, to increase the effectiveness of the lens, the leakage magnetic field from within the enclosed toroidal wiring is minimized. For example, for a non-ideal torii, the wires in toroidal wiring of a magnetic vector potential-based lens may be wrapped helically. This will produce a magnetic field in the toroidal direction of the loop within the solid material of the loop. Accordingly, this improves the focusing properties of the convex lens.

While improving the focusing of the convex lens, such an example wiring may be undesirable for a diverging lens. In another embodiment, an additional return winding of the wire with an opposite helicity is used. The opposing helicity wire would eliminate the undesirable extraneous B-field as well as a lateral E-field from the potential drop across the wire.

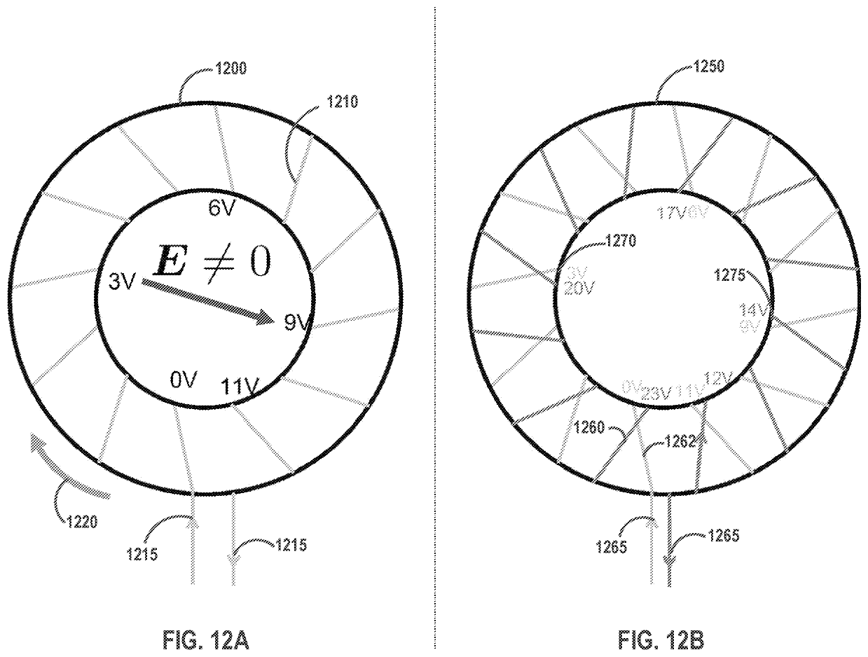

FIG. 12A is a diagram that depicts a helical winding in the counter-poloidal direction for a magnetic vector potential lens, in an embodiment. Toroid 1200 of the lens has helical winding 1210 that is applied in a counter-poloidal direction. Current direction 1215 generates vector potential within the bore of the lens, while also generating the undesirable electric potential/as described by various voltages around the inside of the bore of toroid 1200. Magnetic field 1220 is generated outside toroid 1200 and may also cause a lens aberration.

To further reduce the generation of lateral E-fields and extraneous B-fields, another wiring that can be used is to have multiple wire sections connected in parallel rather than a series winding around the torus. Each individual wire section is wrapped perpendicular to the lens plane with equal separation such that no current flow in the toroidal direction is present. With the parallel connection, the potential drop across each wire will be equivalent such that no E-field will be generated.

FIG. 12B is a diagram that depicts helical winding(s) in both the poloidal and counter-poloidal direction for a magnetic vector potential lens, in an embodiment. Toroid 1250 of the lens has helical winding 1260 that is applied in a counter-poloidal direction and helical winding 1262 that is applied in the poloidal direction. Current direction 1265 generates vector potential within the bore of the lens. However, because the electric fields within the bore generated due to the various voltages for the different windings cancel each other, no electrical field exists within the bore of toroid 1250. Having no or little electrical field removes any aberrations due to such an electrical field.

For example, between point 1270 and 1275 of toroid 1250, for the counter poloidal direction of winding, the potential difference is 6V (9V−3V) in the direction towards point 1275 of toroid 1250 (similar to FIG. 12A). At the same time, for the poloidal direction of winding, the potential difference is similarly 6V (20V−14V) but in the opposite direction, towards point 1270. Accordingly, the electrical fields generated by these potential differences cancel each other out, thereby eliminating aberrations due to the electrical field within the bore of toroid 1250. Therefore, no magnetic field 1220 will be generated outside the toroid because of the opposite helical windings.

The use of superconducting wires can also eliminate potential drops and E-field generation.

Embodiments with slight deviations from the cylindrical symmetry of the torus may also induce stray fields. However, the magnetic vector potential magnitude is proportional to the magnetic flux enclosed within the loop, while any leakage magnetic field is proportional to the current magnitude. Accordingly, for such an embodiment, making the loop volume larger as compared to the current used around the loop lowers the effect of stray magnetic B-fields.

When deviating from cylindrical symmetry, stray magnetic fields in the lens plane can be produced. These magnetic fields can also produce the described convex and concave lensing effects. In this case, the lensing will not be cylindrically symmetric. However, this effect of stray fields is also encompassed by this invention.

In another embodiment, the toroidal coil may be encapsulated inside an electrically conducting material such as another wiring. As long as the conductor is finitely conducting, the magnetic vector potential passes through the conductor after the current is applied to the toroidal wiring. Accordingly, the encapsulating electrically conducting material acts as a shield that allows the magnetic potential to continue to be formed while suppressing stray fields from static and time-varying currents.

In another embodiment in which time-varying currents are applied to the toroidal coil, Aₜ varies in time and produces an electrical field through

$$E = - ∇ V - \frac{\partial A}{\partial t} \qquad ( 19 )$$

where Vis the electric potential. With a time-dependent current, depending on the polarity of the current and its time derivative, an electric field that flows with or against the vector potential is formed. An electron traveling along electric field lines loses momentum, and the radial phase shift profile will be negative relative to an unaffected electron (for an E field distribution like Aₜ). The curvature of the radial phase shift profiles from the vector potential (Δϕ_{A}) and the electric field (Δϕ_{E}) due to a time-dependent current are summarized in Table 1.

TABLE 1
Table of the parameters for a toroidal lens with a time-dependent
current, in an embodiment. A positive current is defined as flowing
in the upwards direction along the inner walls of the torus and opposite
to the electron propagation direction. The arrows (↓↑) indicate
the azimuthal (z) direction of the fields near the axis of the torus.
∩ and ∪ represent the curvature of the phase shift profiles.

| | | | | |
|---|---|---|---|---|
| I | + | + | − | − |
| dI/dt | + | − | + | − |
| A | ↓ | ↓ | ↑ | ↑ |
| dA/dt | + | − | + | − |
| E | ↓ | ↑ | ↓ | ↑ |
| Δϕ_{A} | ∩ | ∩ | ∪ | ∪ |
| Δϕ_{E} | ∩ | ∪ | ∩ | ∪ |

When the polarity of the current and its time derivative are opposite, Δϕ_{A} and Δϕ_{E} are in competition, whereas when the polarities agree, Δϕ_{A} and Δϕ_{E} enhance the overall phase shift profile. Such electric fields from a time-dependent current in a toroidal coil have been used in linear induction accelerators.

### Multiple Lens Configurations

In one or more embodiments, multiple lenses are used to achieve higher optical effectiveness for the lens system. Charged particle beam passing through multiple lenses may produce lesser aberrations and/or higher intensity.

In one embodiment, a magnetic vector potential-based lens is used in combination with any lens(es) for a beam of charged particles that produce spherical aberration. The magnetic vector potential-based lens may correct the spherical aberration of the misfocused beam by tuning the magnetic vector potential-based lens that follows to have the opposite aberration.

In an embodiment, the correcting magnetic potential lens is placed along the azimuthal axis in the direction of the beam. For example, the correcting magnetic potential lens may be placed after the convex focal point around which an aberration exists. In such an example, the magnetic vector potential-based lens having the opposite aberration and being configured to have the same type of focal point may remove the aberration. For example, the magnetic vector potential-based lens may be configured to be convex and focus the charged particle beam that is diverging after the previous imperfect focal point.

FIG. 10 is a schematic that depicts a magnetic vector potential-based lens correcting the spherical aberration of a focusing charged particle lens, in an embodiment. Lens 1010, e.g., a magnetic field-based lens, has convex focal point 1050. Due to positive spherical aberration, the charged particle(s) that enter near the edges of lens 1010 converge at a closer distance than the charged particles that enter near the center of lens 1010 causing a positive spherical aberration. To correct the positive spherical aberration of lens 1010, magnetic vector potential-based lens 1020 is placed after lens 1010, e.g., after focal point 1050. Lens 1020, having negative spherical aberration, re-focuses the charged particle beam onto its convex focal point 1060 without any significant aberration. Accordingly, convex magnetic vector potential-based lens 1020 corrects the spherical aberration of another lens, lens 1020, which in some embodiments is a magnetic field-based lens.

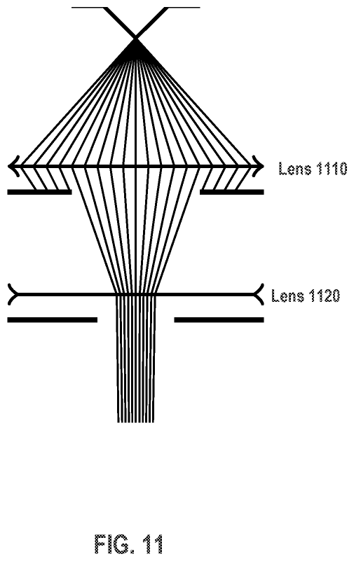

In another embodiment, multiple magnetic potential lenses are stacked to produce different charged particle beam profiles. FIG. 11 is a schematic that depicts two magnetic vector potential-based lenses of opposing type focal points for condensing the passing charged beam profile into a more intense and more parallel beam profile, in an embodiment. Convex magnetic vector potential-based lens 1110 is followed by concave magnetic vector potential-based lens 1120. Such an arrangement has no reversal of image as the lens 1110 first reverses the image, and then lens 1120 reverses it back to the original orientation. Having a larger aperture than other lenses, such as magnetic field-based lenses, lens 1110 may harvest a larger number of charged particles (greater beam intensity) through its aperture (the useful portion of the bore). Lens 1110, being convex, focuses these particles' beam profile closer together, which then lens 1120 being concave lens diverges the beams, making them parallel.

What is claimed is:

1. A charged particle optical apparatus comprising:
a loop of solid material that encloses a bore;
one or more wires poloidally wrapped around the loop:
the one or more wires connected to one or more energy sources;
at least one energy source of the one or more energy sources generating a current through at least one wire of the one or more wires and thereby:
generating a magnetic field inside the loop along a toroidal direction of the loop, and
generating magnetic vector potential within the bore;
one or more charged particles crossing through the bore of the loop;
wherein the one or more charged particles that exit the bore are focused having a focal point of the charged particle optical apparatus.

2. The apparatus of claim 1, wherein the lensing is concave.

3. The apparatus of claim 1, wherein the lensing is convex.

4. The apparatus of claim 1, wherein the loop of solid material has a geometry of a toroid.

5. The apparatus of claim 1, wherein a cross-section of the loop of solid material has a geometry of a polygon.

6. The apparatus of claim 1, wherein the solid material comprises ferromagnetic materials.

7. The apparatus of claim 1, further comprising of shielding material that shields the magnetic field within the loop of solid material from escaping outside.

8. The apparatus of claim 7, wherein the one or more wires are first one or more wires, and the shielding material comprises second one or more wires, the second one or more wires poloidally winded around the loop of solid material externally wrapping the first one or more wires and are coupled to ground.

9. The apparatus of claim 1, wherein the loop of solid material and a first loop of solid material, the bore is a first bore, the one or more wires is first one or more wires, the current is a first current, magnetic vector potential is first magnetic vector potential, the poloidal direction is the first poloidal direction, the focal point is a first focal point, and the first focal point is a convex focal point;
the apparatus further comprising:
a second loop of solid material that encloses a second bore;
second one or more wires poloidally wrapped around the second loop:
the second one or more wires having a second current through at least one wire of the second one or more wires and thereby:
generating second magnetic vector potential within the second bore;
the one or more charged particles crossing through the second bore of the loop;
wherein the one or more charged particles that exit the second bore are focused having a convex focal point of the charged particle optical apparatus, thereby condensing the one or more charged particles exiting the second bore.

10. The apparatus of claim 1, wherein the loop of solid material is a first loop of solid material, the bore is a first bore, the one or more wires is first one or more wires, the current is a first current, magnetic vector potential is first magnetic vector potential, the focal point is a first focal point, and the first focal point is a convex focal point;
the apparatus further comprising of an electromagnetic lens placed above the first loop, the electromagnetic lens comprising of a second loop of solid material that encloses a second bore;
the one or more charged particles crossing the electromagnetic lens through the second bore and thereby generating a second focal point having a spherical aberration;
the one or more charged particles crossing the first bore and condensing on the first focal point that is a convex focal point thereby correcting the spherical aberration of the electrostatic lens.

11. A method comprising:
receiving, by a charged particle lens, a directed stream of one or more charged particles;
generating, by the lens, magnetic vector potential that is at least in part parallel to the direction of the directed stream of the one or more charged particles;
the magnetic vector potential focusing the one or more charged particles to a particular focal point.

12. The method of claim 11, wherein the magnetic vector potential is at least in part in the same direction of the directed stream of the one or more charged particles thereby causing the particular focal point to be a convex focal point.

13. The method of claim 11, wherein the magnetic vector potential is, at least in part, opposite to the direction of the directed stream of the one or more charged particles thereby causing the particular focal point to be a concave focal point.

14. The method of claim 11, further comprising:
applying current to a wire of the lens, poloidally winded around a loop of solid material of the lens thereby generating the magnetic vector potential.

15. The method of claim 14, wherein the one or more charged particles are one or more electrons and wherein the current is applied to the wire in downward poloidal direction around the loop of solid material of the lens thereby generating the magnetic vector potential at least in part in the same direction of the directed stream of the one or more charged particles thereby causing the particular focal point to be a convex focal point.

16. The method of claim 14, the one or more charged particles are one or more electrons and wherein the current is applied to the wire in upward poloidal direction around the loop of solid material of the lens thereby generating the magnetic vector potential at least in part opposite to the direction of the directed stream of the one or more charged particles thereby causing the particular focal point to be a concave focal point.

17. The method of claim 14, wherein the one or more charged particles are one or more positive ions and wherein the current is applied to the wire in downward poloidal direction around the loop of solid material of the lens thereby generating the magnetic vector potential at least in part in the same direction of the directed stream of the one or more charged particles thereby causing the particular focal point to be a concave focal point.

18. The method of claim 14, the one or more charged particles are one or more positive ions and wherein the current is applied to the wire in upward poloidal direction around the loop of solid material of the lens thereby generating the magnetic vector potential at least in part opposite to the direction of the directed stream of the one or more charged particles thereby causing the particular focal point to be a convex focal point.

19. The method of claim 11,
wherein the lens is a first lens, the magnetic vector potential is first magnetic vector potential, the particular focal point is a convex focal point;
the method further comprising:
after receiving the one or more charged particles by the first lens, receiving, by a second lens, the directed stream of the one or more charged particles;
generating, by the second lens, second magnetic vector potential that is at least in part is parallel to direction of the directed stream of the one or more charged particles;
the second magnetic vector potential focusing the one or more charged particles to a concave focal point, thereby condensing the one or more charged particles that exit the second lens.

20. The method of claim 11, wherein the lens is a first lens, and the particular focal point is a first convex focal point, the method further comprising:
before receiving by the first lens, receiving, by a second lens, the directed stream of one or more charged particles;
generating, by the lens, a magnetic field that is at least in part is parallel to direction of the directed stream of the one or more charged particles;
the magnetic field focusing the one or more charged particles to a second convex focal point;
wherein the magnetic vector potential focusing the one or more charged particles to the first convex focal point causes correcting spherical aberration generated by the second lens.
